(19) United States
(12) Patent Application Publication
(10) Pub. No.: US 2019/0361294 A1
(43) Pub. Date: Nov. 28, 2019

(54) PLANAR BACKLIGHT MODULE AND LCD PANEL

(71) Applicant: Wuhan China Star Optoelectronics Technology Co., Ltd., Wuhan City HB (CN)

(72) Inventors: Yong Yang, Wuhan City (CN); Guowei Zha, Wuhan City (CN); Hongqing Cui, Wuhan City (CN)

(21) Appl. No.: 16/096,298

(22) PCT Filed: Sep. 22, 2018
(86) PCT No.: PCT/CN2018/107139

§ 371 Date: Oct. 25, 2018

(30) Foreign Application Priority Data
May 22, 2018 (CN) 201810495944.9

(51) Int. Cl. G02F 1/1335; H01L 25/075; H01L 33/46; H05K 1/18

(52) U.S. Cl. CPC G02F 1/133603; G02F 1/133606; G02F 1/133611; H05K 2201/10106; H01L 33/46; H05K 1/189; H01L 25/0753

(57) ABSTRACT

The present invention teaches a planar backlight module and a LCD panel. The planar backlight module includes a Mini LED substrate, a number of Mini LED chips disposed on the Mini LED substrate, and a fluorescent film covering the Mini LED chips. A top side of the fluorescent film away from the Mini LED chips is configured with a number of micro-structures for achieving light of greater emission angle and enhancing the brightness uniformity even without an optical film set. The planar backlight module therefore may further achieve better transmittance and greater brightness. The planar backlight module is also more appropriate for thinning.

### FIELD OF THE INVENTION

The present invention is generally related to the field of display technology, and more particularly to a planar backlight module and a liquid crystal display (LCD) panel.

### BACKGROUND OF THE INVENTION

Liquid crystal display (LCD) is the mainstream display device and, due to its high quality, power efficiency, thin dimension, and high applicability, is widely applied to consumer appliances such as mobile phones, televisions, personal digital assistants, digital camera, notebook computers, desktop calculators, etc. Most LCD devices are back-lighted LCD devices which include a LCD panel and a backlight module. The working principle of a LCD panel is placing liquid crystal molecules between two parallel glass substrates, and applying electricity through many vertical and horizontal wires on the substrates to alter the angles of the liquid crystal molecules, thereby refracting the light from the backlight module. As the LCD panel itself does not self-illuminate, to display images on the LCD panel requires the light provided by the backlight module. Therefore, the backlight module is a key component to the LCD device. There are two types of backlight modules, depending on how light is incident into the LCD panel: the edge-lit backlight module and the direct-lit backlight module.

As shown in FIGS. 1 and 2, a conventional direct-lit backlight module uses an array of light emitting diodes (LEDs) to provide a planar light source, and includes a LED substrate 100, multiple LED chips 200, a fluorescent film 300, a diffusion sheet 400, and a brightness enhancement film 500. The light from an LED has the Lambertian distribution, meaning that the brightness decreases as the distance to the LED increases. This is a main reason that direct-lit backlight module has non-uniform brightness. Currently, this problem is mostly resolved by using diffusion sheet or adding scattering haze particles in the fluorescent film. However, adding additional film would result in reduction of the light transmittance and affect the overall brightness. Adding haze particles also provides limited improvement.

### SUMMARY OF THE INVENTION

An objective of the present invention is to teach a planar backlight module providing a planar light of uniform brightness.

Another objective of the present invention is to provide a LCD panel having a smaller thickness and a better color saturation.

To achieve the objectives, the present invention teaches a planar backlight module including a Mini LED substrate, multiple Mini LED chips disposed at intervals on the Mini LED substrate, and a fluorescent film covering the Mini LED chips.

A top side of the fluorescent film away from the Mini LED chips is configured with a plurality of micro-structures.

Each micro-structure has an incomplete spherical shape concaved towards the Mini LED chips.

The incomplete spherical shape has a radius of curvature between 50 μm and 1000 μm; a distance between a Mini LED chip and a bottom side of a corresponding micro-structure is between 150 μm and 250 μm; two neighboring micro-structures are separated by a distance between 700 μm and 1500 μm; and the micro-structures have a width between 100 μm and 1000 μm.

The micro-structures are formed by imprinting or etching the top side of the fluorescent film.

Each micro-structure is disposed correspondingly to a Mini LED chip.

Each micro-structure is directly above a corresponding Mini LED chip.

Each micro-structure covers the corresponding Mini LED chip.

The Mini LED substrate is a rigid or flexible printed circuit board (PCB).

The Mini LED chips are arranged regularly in an array on the Mini LED substrate.

The planar backlight module further comprises a diffusion sheet and a brightness enhancement film sequentially disposed on the fluorescent film.

The present invention also teaches a liquid crystal display (LCD) panel including the above described planar backlight module.

The advantages of the present invention are as follows. The planar backlight module of the present invention includes a Mini LED substrate, a number of Mini LED chips disposed on the Mini LED substrate, and a fluorescent film covering the Mini LED chips. A top side of the fluorescent film away from the Mini LED chips is configured with a number of micro-structures for achieving light of greater emission angle and enhancing the brightness uniformity even without an optical film set. The planar backlight module therefore may further achieve better transmittance and greater brightness. The planar backlight module is also more appropriate for thinning. A LCD panel of the present invention includes the above described planar backlight module. The LCD panel is therefore thinner and has better color saturation and brightness.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a schematic diagram showing a conventional LED planar light source.

FIG. 2 is a schematic diagram showing a conventional direct-lit backlight module.

FIG. 3 is a schematic diagram showing a planar backlight module according to a first embodiment of the present invention.

FIG. 4 is a schematic diagram showing a planar backlight module according to a first embodiment of the present invention.

FIG. 5 shows brightness distribution on a front side of a planar backlight module whose fluorescent film is configured with micro-structures.

FIG. 6 shows brightness distribution on a front side of a planar backlight module whose fluorescent film is not configured with micro-structures.

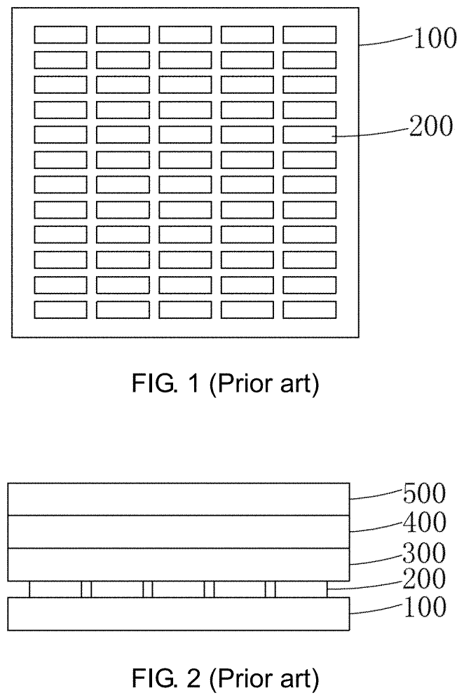

### DETAILED DESCRIPTION OF PREFERRED EMBODIMENTS

The following descriptions for the respective embodiments are specific embodiments capable of being implemented for illustrations of the present invention with referring to appended figures.

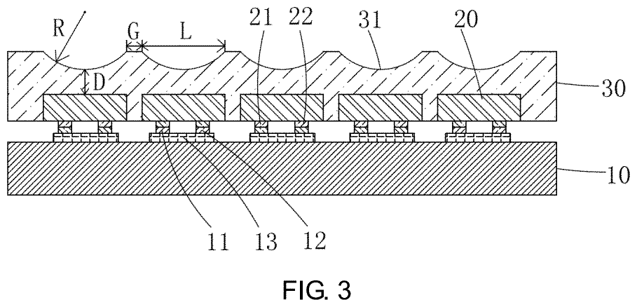

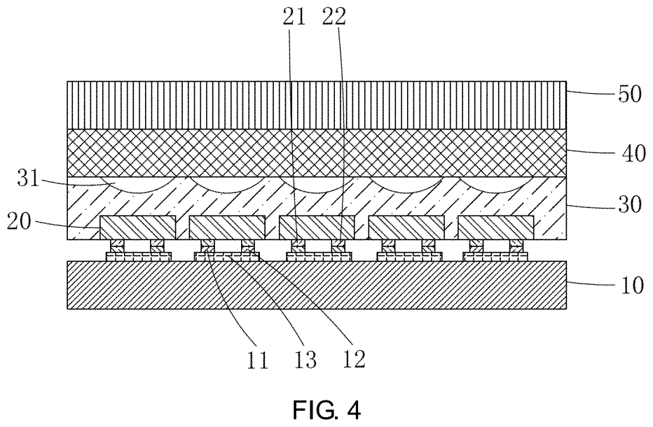

As shown in FIG. 3, a planar backlight module according to a first embodiment of the present invention includes a Mini LED substrate 10, a number of Mini LED chips 20 above the Mini LED substrate 10, and a fluorescent film 30 covering the Mini LED chips 20. A top side of the fluorescent film 30 away from the Mini LED chips 20 is configured with a number of micro-structures 31 for improving the light mixing effect and enhancing the brightness uniformity of the planar backlight module. Compared to the prior art, the present embodiment achieves uniform brightness without installing an additional optical film set on the fluorescent film 30. However, if required, a second embodiment of the present invention shown in FIG. 4 still have the optical film set disposed on the fluorescent film 30 to further enhance brightness uniformity. The optical film set includes a diffusion sheet 40 and a brightness enhancement film 50 sequentially disposed on the fluorescent film 30 for evenly diffusing but collimating light toward positive viewing direction.

Specifically, each micro-structure 31 has an incomplete spherical shape concaved towards the side with Mini LED chips 20. These micro-structures 31 alter the light diffusion characteristics of the Mini LED chips 20 so as to achieve uniform light mixing. Of course, the micro-structures 31 may also have other shapes capable of light mixing.

Specifically, the micro-structures 31 have a radius of curvature R between 50 μm and 1000 μm. A distance D between a Mini LED chip 20 and a bottom side of a corresponding micro-structure 31 is between 150 μm and 250 μm. Two neighboring micro-structures 31 are separated by a distance G between 700 μm and 1500 μm. The micro-structures 31 have a width L between 100 μm and 1000 μm.

Specifically, the micro-structures 31 are formed by imprinting on a flat top side of the fluorescent film 30 using a mold after the fluorescent film 39 is coated on the entire Mini LED substrate 10. Alternatively, the micro-structures 31 may also be formed by etching the flat top side of the fluorescent film 30.

Specifically, each micro-structure 31 is disposed correspondingly to a Mini LED chip 20. Furthermore, the micro-structure 31 is directly above and covers the corresponding Mini LED chip 20.

Specifically, the Mini LED substrate 10 is a printed circuit board (PCB). Furthermore, the Mini LED substrate 10 may be a rigid or flexible PCB. Of course, if required, the Mini LED substrate 10 may also an integrated rigid and flexible PCB.

Specifically, a bottom side of the Mini LED substrate 10 adjacent to the Mini LED chips 20 is configured with wire layout (not shown) and a number of pads 13 electrically connected to the wire layout and respectively corresponding to the Mini LED chips 20. Each pad 13 is electrically connected to the corresponding Mini LED chip 20 so as to power the Mini LED chip 20.

Specifically, the Mini LED chips 20 are flip-chip packaged and each Mini LED chip 20 has separated P electrode 21 and N electrode 22. Each pad 13 has separated first contact 11 and second contact 12. Each Mini LED chip 20 has its P and N electrodes 21 and 22 electrically connected to the first and second contacts 11 and 12 of the corresponding pad 13 through solder paste. The heat produced by the Mini LED chips 20 may be quickly dissipated to the Mini LED substrate 10 through the pads 13. The planar backlight module therefore has superior heat dissipation capability, and may effectively avoid the optical quenching problem.

Specifically, the fluorescent film 30 is a wavelength conversion film, and may convert short-wavelength blue light to long wave-length red and green light.

Specifically, a top side of the Mini LED substrate 10 adjacent to the Mini LED chips 20 is coated with a material of high reflectivity so as to achieve better light utilization. Preferably, the material of high reflectivity is coated outside the pads 13. That is, the material of high reflectivity does not cover the pads 13 of the Mini LED substrate 10 so as to prevent inferior contact between the Mini LED chips 20 and their electrically connected pads 13.

Specifically, the Mini LED chips 20 are arranged regularly in an array on the Mini LED substrate 10 so as to facilitate uniform brightness of the planar backlight module.

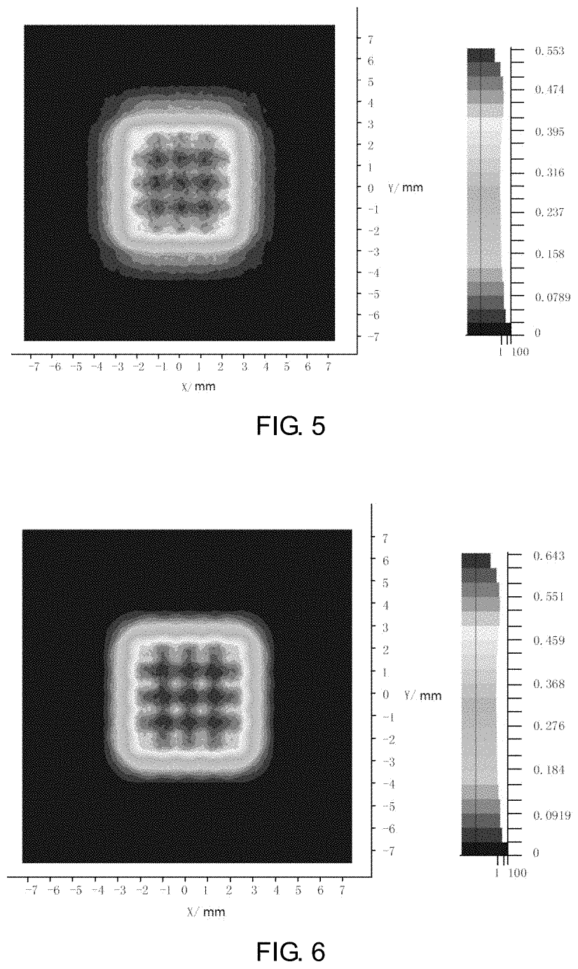

FIG. 5 shows brightness distribution on a front side of a planar backlight module whose fluorescent film 30 is configured with micro-structures 31. FIG. 6 shows brightness distribution on a front side of a planar backlight module whose fluorescent film 30 is not configured with micro-structures 31. For the planar backlight modules of FIGS. 5 and 6, they both have an array of 5×5 Mini LED chips. Each Mini LED chip has a front lighting angle of 120°. For the micro-structures 31, the radius of curvature R is 780 μm, the width L is 600 μm, the height H is 60 μm, the distance D between Mini LED and micro-structure 31 is 240 μm, and a distance G between two neighboring micro-structures 31 is 1150 μm. As illustrated, the brightness distribution of FIG. 5 is more uniform than that of FIG. 6. Through further data analysis, the mean square errors for the brightness distributions of FIGS. 5 and 6 are respectively 0.12 and 0.147, indicating that fluorescent film 30 with micro-structures 31 may achieve more uniform brightness distribution.

Based on the above described planar backlight module, the present invention also teaches a liquid crystal display (LCD) panel including the above described planar backlight module.

As described above, the planar backlight module of the present invention includes a Mini LED substrate, a number of Mini LED chips disposed on the Mini LED substrate, and a fluorescent film covering the Mini LED chips. A top side of the fluorescent film away from the Mini LED chips is configured with a number of micro-structures for achieving light of greater emission angle and enhancing the brightness uniformity even without an optical film set. The planar backlight module therefore may further achieve better transmittance and greater brightness. The planar backlight module is also more appropriate for thinning. A LCD panel of the present invention includes the above described planar backlight module. The LCD panel is therefore thinner and has better color saturation and brightness.

Above are embodiments of the present invention, which does not limit the scope of the present invention. Any equivalent amendments within the spirit and principles of the embodiment described above should be covered by the protected scope of the invention.

What is claimed is:

1. A planar backlight module, comprising a Mini light emitting diode (LED) substrate, a plurality of Mini LED chips disposed at intervals on the Mini LED substrate, and a fluorescent film covering the Mini LED chips, wherein a top side of the fluorescent film away from the Mini LED chips is configured with a plurality of micro-structures.

2. The planar backlight module according to claim 1, wherein each micro-structure has an incomplete spherical shape concaved towards the Mini LED chips.

3. The planar backlight module according to claim 2, wherein the incomplete spherical shape has a radius of curvature between 50 μm and 1000 μm; a distance between a Mini LED chip and a bottom side of a corresponding micro-structure is between 150 μm and 250 μm; two neighboring micro-structures are separated by a distance between 700 μm and 1500 μm; and the micro-structures have a width between 100 μm and 1000 μm.

4. The planar backlight module according to claim 1, wherein the micro-structures are formed by imprinting or etching on the top side of the fluorescent film; and each micro-structure is disposed correspondingly to a Mini LED chip.

5. The planar backlight module according to claim 4, wherein each micro-structure is directly above a corresponding Mini LED chip.

6. The planar backlight module according to claim 5, wherein each micro-structure covers the corresponding Mini LED chip.

7. The planar backlight module according to claim 1, wherein the Mini LED substrate is a rigid or flexible printed circuit board (PCB).

8. The planar backlight module according to claim 1, wherein the Mini LED chips are arranged regularly in an array on the Mini LED substrate.

9. The planar backlight module according to claim 1, further comprising a diffusion sheet and a brightness enhancement film sequentially disposed on the fluorescent film.

10. A liquid crystal display (LCD) panel, comprising the planar backlight module as claimed in claim 1.
